(19) United States
(12) Patent Application Publication
(10) Pub. No.: US 2024/0178197 A1
(43) Pub. Date: May 30, 2024

(54) MICRO LIGHT-EMITTING DIODE DISPLAY DEVICE AND MANUFACTURING METHOD OF THE SAME

(71) Applicant: PlayNitride Display Co., Ltd., Zhunan Township (TW)

(72) Inventors: YEN-YEH CHEN, Zhunan Township (TW); YU-JUI TSENG, Zhunan Township (TW)

(21) Appl. No.: 18/085,987

(22) Filed: Dec. 21, 2022

(30) Foreign Application Priority Data
Nov. 28, 2022 (TW) 111145511

(51) Int. Cl. H01L 25/075; H01L 33/00; H01L 33/54; H01L 33/62

(52) U.S. Cl. CPC H01L 25/0753; H01L 33/005; H01L 33/54; H01L 33/62; H01L 2933/005; H01L 2933/0066

(57) ABSTRACT

A micro LED display device and manufacturing method thereof. The micro LED display device includes a circuit substrate, a pixel structure layer, a support structure, a connection layer and a protection layer. The pixel structure layer is disposed on the top surface of the circuit substrate, and has plural micro LED units disposed separately. The micro LED units face the top surface and are electrically connected with the circuit substrate. The support structure is disposed on the top surface, extending from the top surface to the pixel structure layer and connected with the side surface of the pixel structure layer. The support structure protrudes from a surface of the pixel structure layer away from the circuit substrate. The connection layer is disposed in the accommodating space formed by the support structure and the surface of the pixel structure layer. The protection layer is disposed on the connection layer.

### CROSS REFERENCE TO RELATED APPLICATIONS

This Non-provisional application claims priority under 35 U.S.C. § 119(a) on Patent Application No(s). 111145511 filed in Taiwan, Republic of China on Nov. 28, 2022, the entire contents of which are hereby incorporated by reference.

### BACKGROUND

### Technology Field

The present disclosure relates to a display device and, in particular, to a micro light-emitting diode (LED) display device and the manufacturing method of the same.

### Description of Related Art

Now the world is paying attention to the future display technology, and micro light-emitting diode (micro LED or μLED) is one of the most promising technologies. In brief, micro LED is a technology of miniaturizing and rearranging LEDs, thereby arranging millions or even tens of millions of dies, which are smaller than 100 microns and thinner than a hair, on a substrate. Compared with the current OLED (organic light-emitting diode) display technology, micro LED display device is also a self-luminous device but utilizes different material. Therefore, the micro LED display device can solve the screen burn-in issue, which is the most deadly problem in OLED display device. Besides, micro LED display device further has the advantages of low power consumption, high contrast, wide color gamut, high brightness, small and thin size, light weight and energy saving. Therefore, major factories around the world are scrambling to invest in the research and development of micro LED technology.

In the micro LED display device, the light-emitting layers of micro LEDs are easily affected by moisture or dusts so as to damage the properties thereof. In order to prevent the damage of the light-emitting layers caused by the intrusion of moisture and dusts, a protection member with functions such as buffering or waterproofing is generally provided for protecting the micro LED display device from the intrusion of moisture and dusts, thereby remaining the properties of the micro LED display device and improving the lifetime of the micro LED display device.

Therefore, it is desired to provide a micro LED display device that can prevent the intrusion of moisture and dusts so as to remain the properties of the micro LED display device and improve the lifetime thereof.

### SUMMARY

One or more exemplary embodiments of this disclosure are to provide a micro LED display device and a manufacturing method of the same, which can prevent the intrusion of moisture and dusts, thereby remaining the properties of the micro LED display device and improving the lifetime thereof.

In an exemplary embodiment, a micro LED display device includes a micro light-emitting diode display device, which includes a circuit substrate, a pixel structure layer, a support structure, a connection layer and a protection layer. The circuit substrate has a top surface and a side surface. The pixel structure layer is disposed on the top surface of the circuit substrate, and has a plurality of micro LED units disposed separately. The micro LED units face the top surface of the circuit substrate and are electrically connected with the circuit substrate. The support structure is disposed on the top surface of the circuit substrate, extending from the top surface of the circuit substrate to the pixel structure layer, and connected with the side surface of the pixel structure layer. The support structure protrudes from a surface of the pixel structure layer away from the circuit substrate, and the support structure and the surface of the pixel structure layer form an accommodating space. The connection layer is disposed in the accommodating space, and the protection layer is disposed on the connection layer.

In an exemplary embodiment, a manufacturing method of a micro light-emitting diode display device includes the following steps of: providing a circuit substrate and a temporary substrate, wherein the circuit substrate has a top surface, the temporary substrate comprises a carrier plate, a bonding layer and a pixel structure layer, the pixel structure layer is disposed on the carrier plate via the bonding layer, and the pixel structure layer has a plurality of micro light-emitting diode units disposed separately; aiming the micro light-emitting diode units of the pixel structure layer toward the top surface and electrically connecting the micro light-emitting diode units with the circuit substrate; forming a support structure on the top surface of the circuit substrate, extending the support structure from the top surface to a side surface of the pixel structure layer, and connecting the support structure with the pixel structure layer, the bonding layer and the carrier plate; removing the carrier plate and the bonding layer to expose a surface of the pixel structure layer, wherein the support structure protrudes from the surface of the pixel structure layer away from the circuit substrate, and the support structure and the surface of the pixel structure layer form an accommodating space; forming a connection layer in the accommodating space; and disposing a protection layer on the connection layer, so that the protection layer is connected with the pixel structure layer via the connection layer.

As mentioned above, in the micro LED display device and the manufacturing method of the same of this disclosure, the pixel structure layer is disposed on the top surface of the circuit substrate and includes a plurality of micro LED units arranged separately, and the micro LED units face the top surface and are electrically connected with the circuit substrate. The support structure is disposed on the top surface of the circuit substrate, extending from the top surface of the circuit substrate to the pixel structure layer, and connected with the side surface of the pixel structure layer. The support structure protrudes from a surface of the pixel structure layer away from the circuit substrate, and the support structure and the surface of the pixel structure layer form an accommodating space. The connection layer is disposed in the accommodating space, and the protection layer is disposed on the connection layer. Based on the structural design of this disclosure, the micro LED display device can prevent the intrusion of moisture and dusts, thereby remaining the properties of the micro LED display device and improving the lifetime thereof.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a schematic diagram showing a micro LED display device according to an embodiment of this disclosure;

FIG. 1B is a schematic sectional view of the micro LED display device according to an embodiment of this disclosure;

FIGS. 2A to 2E are schematic sectional views of micro LED display devices according to different embodiments of this disclosure; and

FIGS. 3A to 3E are schematic sectional views showing the manufacturing procedure of a micro LED display device according to an embodiment of this disclosure.

### DETAILED DESCRIPTION OF THE DISCLOSURE

The present disclosure will be apparent from the following detailed description, which proceeds with reference to the accompanying drawings, wherein the same references relate to the same elements.

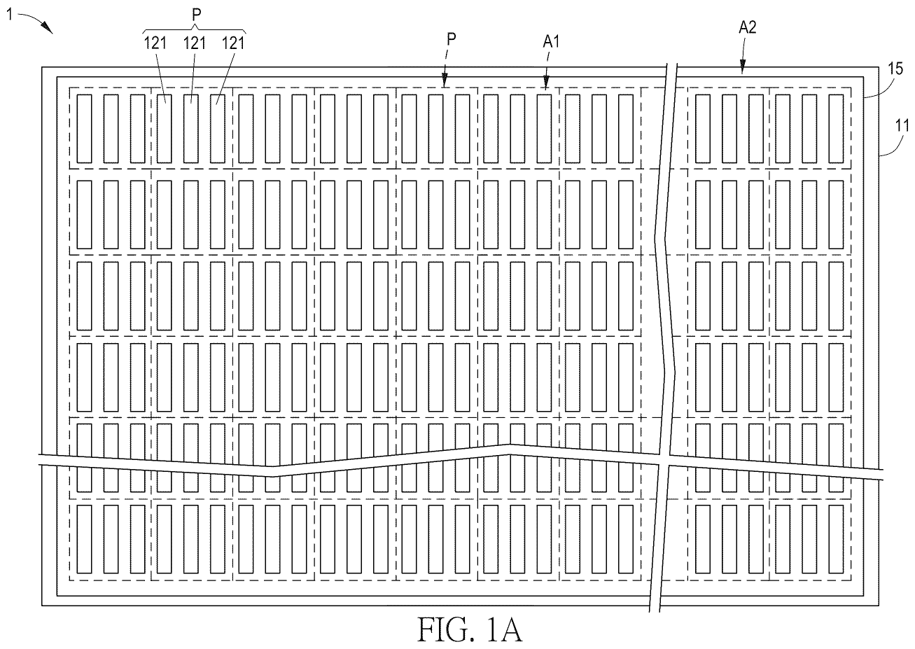

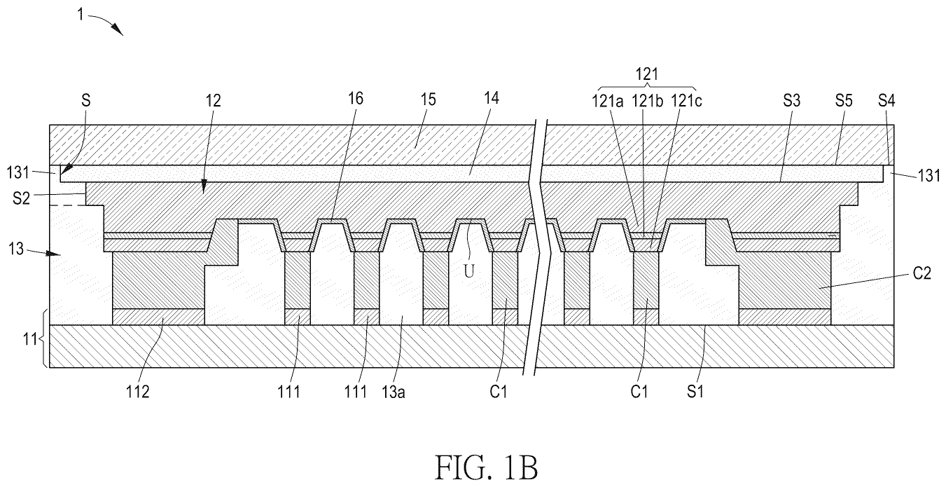

FIG. 1A is a schematic diagram showing a micro LED display device 1 according to an embodiment of this disclosure, and FIG. 1B is a schematic sectional view of the micro LED display device 1.

With reference to FIGS. 1A and 1B, the micro LED display device 1 can be an AM (Active Matrix) micro LED display device or a PM (Passive Matrix) micro LED display device. In this embodiment, the micro LED display device 1 includes a circuit substrate 11, a pixel structure layer 12, a support structure 13, a connection layer 14, and a protection layer 15.

The micro LED display device 1 includes a plurality of pixels P, which are arranged in a matrix with multiple rows and columns. In this embodiment, each pixel P includes three sub-pixels arranged side by side, and each sub-pixel includes a micro LED unit 121. That is, each pixel P includes three micro LED units 121 arranged side by side. In other embodiments, the three sub-pixels in each pixel P can be arranged in a different way. For example, two of the three sub-pixels are arranged up and down, and the third one of the three sub-pixels is located beside the other two sub-pixels. To be noted, other arrangements are also acceptable. In different embodiments, each pixel P may include four or more sub-pixels. Taking the pixel P including four sub-pixels as an example, the four sub-pixels can be arranged side by side, or in a 2*2 array, or any of other suitable arrangements. This disclosure is not limited thereto.

The circuit substrate 11 includes a display area A1 and a non-display area A2. The display area A1 is the area of the micro LED display device 1 for displaying images, which corresponds to the positions of the pixels P (the micro LED units 121). The non-display area A2 is located at the periphery of the display area A1, which is the area for arranging the driving components (e.g. IC) or circuits. The circuit substrate 11 has a top surface S1. The circuit substrate 11 can be a driving substrate for driving the micro LED units 121 to emit light. For example, the circuit substrate 11 may be a complementary metal-oxide-semiconductor (CMOS) substrate, a liquid crystal on silicon (LCOS) substrate, or a thin-film transistor (TFT) substrate, or any of other circuit substrates with working circuits, but this disclosure is not limited thereto. To be noted, in the following description, the term “thickness” or “height” is defined as a thickness or height in the direction perpendicular to the top surface S1 of the circuit substrate 11, and the term “width” or “size” is defined as a width or size in the direction parallel to the top surface S1 of the circuit substrate 11.

The pixel structure layer 12 is disposed on the top surface S1 of the circuit substrate 11. In this case, the pixel structure layer 12 has a plurality of micro LED units 121 arranged separately with constant intervals or not, and these micro LED units 121 face the top surface S1 of the circuit substrate 11 and are respectively electrically connected to the circuit substrate 11. Accordingly, the micro LED units 121 can be controlled (driven) to emit light through the circuit substrate 11. In this embodiment, the surface of the pixel structure layer 12 facing the circuit substrate 11 is formed with a plurality of recesses U to separate the array-arranged micro LED units 121, and each micro LED unit 121 can be independently controlled to emit light. In addition, the pixel structure layer 12 further has a side surface S2.

In this embodiment, each micro LED unit 121 can provide the light source for one corresponding sub-pixel, and each micro LED unit 121 comprises a first type semiconductor layer 121a, a light-emitting layer 121b, and a second type semiconductor layer 121c, which are stacked in order. The light-emitting layer 121b is sandwiched between the first type semiconductor layer 121a and the second type semiconductor layer 121c. Specifically, the pixel structure layer 12 includes a continuous first type semiconductor layer 121a (i.e. a common N-type structure), so that all of the micro LED units 121 may share the first type semiconductor layer 121a in common. To be noted, this disclosure is not limited thereto. In addition, each second type semiconductor layer 121c is, for example, a P-type semiconductor layer, and each light-emitting layer 121b is, for example, a multiple quantum well (MQW) layer. This disclosure is not limited thereto. In different embodiments, the first type semiconductor layer 121a can be a P-type semiconductor layer (e.g. a common P-type structure), and the second type semiconductor layer 121c can be an N-type semiconductor layer. In this case, the micro LED units 121 commonly utilizes the single P-type semiconductor layer.

In addition, the circuit substrate 11 of this embodiment further includes a plurality of conductive electrodes (111, 112), which are disposed corresponding to the micro LED units 121 of the pixel structure layer 12 (e.g. in the one-to-one arrangement). In this embodiment, each conductive electrode is electrically connected to the corresponding circuit layer (not shown) of the circuit substrate 11. Accordingly, the circuit substrate 11 can transmit the individually controlled electric signal to the conductive electrode through the corresponding circuit layer, thereby driving the corresponding micro LED unit 121 to emit light.

The conductive electrodes of this embodiment may include a plurality of first electrodes 111 and a second electrode 112 arranged around the periphery of the micro LED units 121. Each first electrode 111 is electrically connected to the second type semiconductor layer 121c of one corresponding micro LED unit 121 via one corresponding conductive member C1, and the second electrode 112 is the common electrode of the pixel structure layer 12 and is electrically connected to the first type semiconductor layers 121a of the corresponding micro LED units 121 via one corresponding conductive member C2. To be noted, those skilled person in the art should understand that the conductive member C2 (as well as the second electrode 112) is not limited to be arranged around the periphery of the micro LED units 121 on the top surface S1 of the circuit substrate 11. The above-mentioned conductive members C1 and C2 can include, for example but not limited to, indium, tin, copper, silver, gold, or an alloy thereof (e.g., copper plus any of the above-mentioned metals (excluding tin)), and this disclosure is not limited. In addition, in the micro LED units 121, excepting the areas contacting the conductive members C1 and C2, the surface of the micro LED unit 121 facing the circuit substrate 11 is provided with an insulating layer 16, which is used to protect the structure of the micro LED unit 121. In other words, the insulating layer 16 is disposed on the areas of the bottom surface of the pixel structure layer 12 that is not in contact with the conductive members C1 and C2.

The support structure 13 is disposed on the top surface S1 of the circuit substrate 11. The support structure 13 extends from the top surface S1 of the circuit substrate 11 to the pixel structure layer 12, and is connected with the side surface S2 of the pixel structure layer 12. In this case, the support structure 13 protrudes from a surface S3 of the pixel structure layer 12 away from the circuit substrate 11, and the support structure 13 and the surface S3 of the pixel structure layer 12 form an accommodating space S. In this embodiment, the support structure 13 is arranged on the non-display area A2 and surrounds the periphery of the display area A1. In this case, the support structure 13 protrudes from the surface S3 of the pixel structure layer 12 to form a retaining wall 131, and the retaining wall 131 and the (top) surface S3 of the pixel structure layer 12 away from the circuit substrate 11 together form the accommodating space S. In some embodiments, the support structure 13 can be made of transparent curable insulating material, or curable insulating materials of other colors. For example, a black support structure 13 can prevent the occurrence of crosstalk, while a white support structure 13 has the reflection effect so as to increase the light output rate. In some embodiments, the support structure 13 can be made of insulating gel, such as silica gel or/and epoxy resin. In some embodiments, the height of the retaining wall 131 may be greater than 1300 μm. To be noted, if the height of the retaining wall 131 is insufficient, the connection layer 14 made by the following process may be too thin to connect the protection layer 15 stably, and the yield rate will be decreased. In some embodiments, the width of the retaining wall 131 needs to be greater than 10 μm. To be noted, if the width of the retaining wall 131 is too small, it may be easily broken and the yield rate will be reduced.

In addition, the micro LED display device 1 of this embodiment further includes a filling layer 13a. In this case, the filling layer 13a is an insulating layer, which is disposed between the pixel structure layer 12 and the top surface S1 of the circuit substrate 11. In addition to providing a buffer during the pressing process to avoid cracking of the pixel structure layer 12 and to fix the position of the micro LED units 121, the filling layer 13a can further prevent the short circuit between the first electrode 111 and the second electrode 112. However, due to process factors, the gap between the pixel structure layer 12 and the top surface S1 of the circuit substrate 11 may not be fully filled by the filling layer 13a. Therefore, in some embodiments, the filling layer 13a may contain an air bubble. In some embodiments, the material of the filling layer 13a may include organic polymer materials such as photoresist and ink. In some embodiments, the filling layer 13a can be an insulating gel, and the material thereof includes, for example, silica gel or/and epoxy resin.

In some embodiments, the support structure 13 and the filling layer 13a can be integrally formed as one piece. In other words, the support structure 13 and the filling layer 13a has an integrated structure that is made by the same process and the same material. Accordingly, the filling layer 13a can be filled between the pixel structure layer 12 and the top surface S1 of the circuit substrate 11, while the support structure 13 is formed surrounding the periphery of the pixel structure layer 12 and contacting the sider surface S2. In addition, the support structure 13 further protrudes from the side surface S2 so as to form a retaining wall 131, thereby forming the accommodating space S for receiving the connection layer 14.

The connection layer 14 is disposed in the accommodating space S. In this embodiment, the connection layer 14 is made of a transparent and insulating material, which is fully filled within the accommodating space S. In other words, the connection layer 14 is located in the accommodating space S and is closely connected with the support structure 13 (the retaining wall 131). In this case, the support structure 13 (the retaining wall 131) can define the shape and thickness of the connection layer 14. Specifically, in this embodiment, the thickness of the thickness of the connection layer 14 is identical to the height of the retaining wall 131. In some embodiments, the thickness of the connection layer 14 must be less than 1300 μm. If the connection layer 14 is too thick, the redundant material of the connection layer 14 may flow over the retaining wall 131 to form the redundant gel during the process of connecting the protection layer 15 on the connection layer 14. In addition, the connection layer 14 with a smaller thickness may be benefit in reducing the cross-talk phenomenon.

The protection layer 15 is disposed on the connection layer 14. Herein, the top surface S5 of the connection layer 14 is leveled or aligned with the top surface S4 of the support structure 13, and the connection layer 14 is located between the protection layer 15 and the pixel structure layer 12, so that the protection layer 15 can connect to the pixel structure layer 12 through the connection layer 14. In this embodiment, the protection layer 15 is disposed (covering) on the top surface S4 of the retaining wall 131 and the top surface S5 of the connection layer 14, and the bottom surface of the protection layer 15 directly contacts and connects the top surface S4 of the retaining wall 131 and the top surface S5 of the connection layer 14. Moreover, the size of the protection layer 15 is greater than that of the connection layer 14; that is, the projection area of the protection layer 15 on the circuit substrate 11 is greater than the projection area of the connection layer 14 on the circuit substrate 11. The projection of the protection layer 15 on the circuit substrate 11 is located within the projections of the connection layer 14 and the support structure 13 on the circuit substrate 11. That is, the projection area of the protection layer 15 on the circuit substrate 11 is equal to the projection areas of the connection layer 14 and the support structure 13 on the circuit substrate 11 (i.e., the projection of the protection layer 15 on the circuit substrate 11 is totally overlapped with the projections of the connection layer 14 and the support structure 13 on the circuit substrate 11). In other embodiments, the projection of the protection layer 15 on the circuit substrate 11 is slightly smaller than the projections of the connection layer 14 and the support structure 13 on the circuit substrate 11. That is, the projection area of the protection layer 15 on the circuit substrate 11 is less than the projection areas of the connection layer 14 and the support structure 13 on the circuit substrate 11. Herein, the projection of the protection layer 15 on the circuit substrate 11 is greater than the projection of the connection layer 14 on the circuit substrate 11. This design can completely protect the micro LED units 121 and the circuit substrate 11 from the intrusion of moisture or dusts, thereby increasing the lifetime of the electronic products.

In this embodiment, the material of the protection layer 15 is different from that of the connection layer 14. In some embodiments, the protection layer 15 is made of a light-transmitting material, and can be a rigid board, a flexible board, or a combination board including rigid and flexible boards. For example, the material of the protection layer 15 can be a glass substrate, a polyimide (PI) substrate, or a composition film at least including the above-mentioned materials. In this embodiment, for example, the protection layer 15 is a glass substrate, and the connection layer 14 includes an organic polymer material such as, for example but not limited to, resin. In some embodiments, the thickness of the protection layer 15 is greater than 100 μm. In addition, the Young's modulus (also known as elastic modulus) of the protection layer 15 in this embodiment is greater than that of the support structure 13, and the Young's modulus of the protection layer 15 is also greater than that of the connection layer 14. Therefore, the protection layer 15 can provide a better protection effect, and also provide a buffer when connecting the support structure 13 and the connection layer 14.

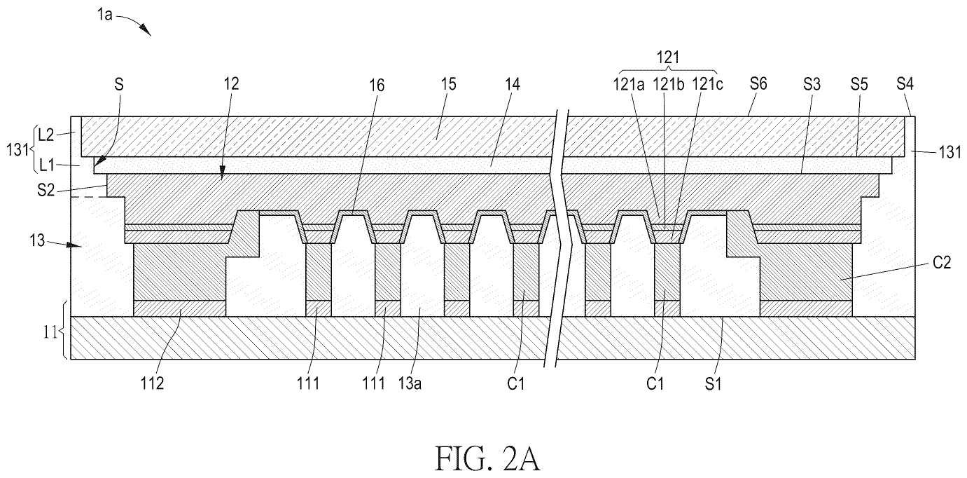

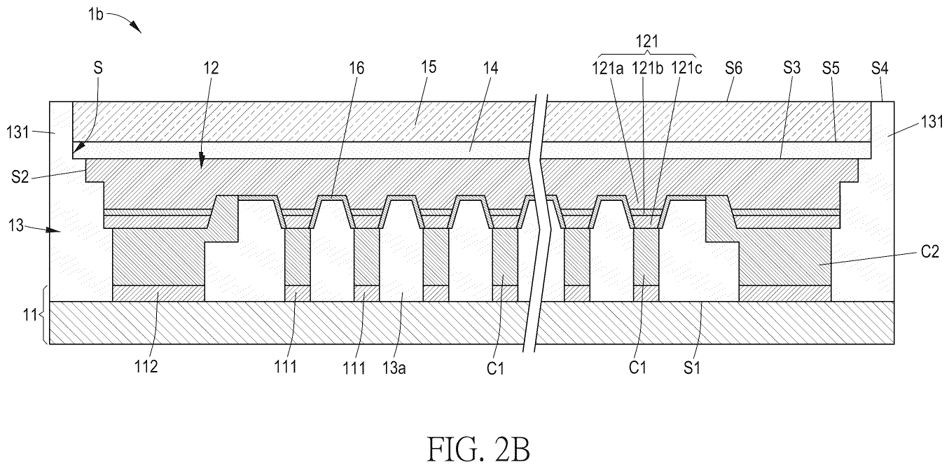

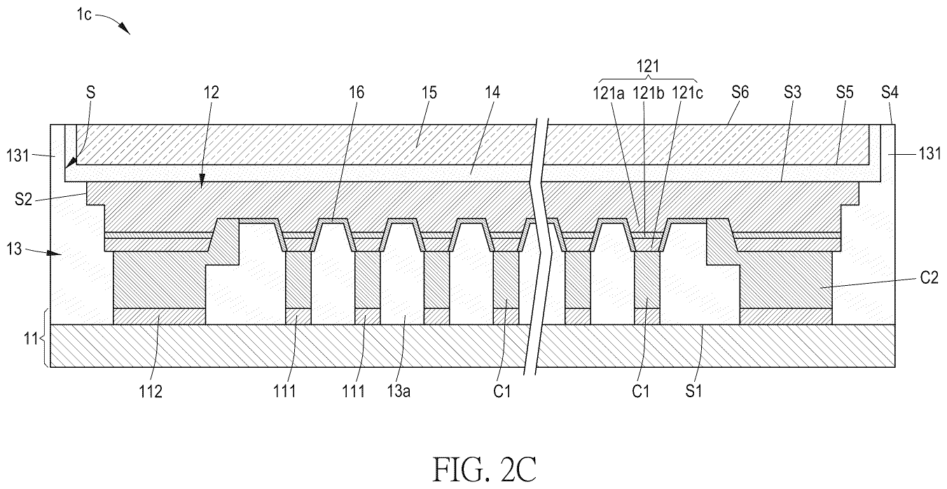

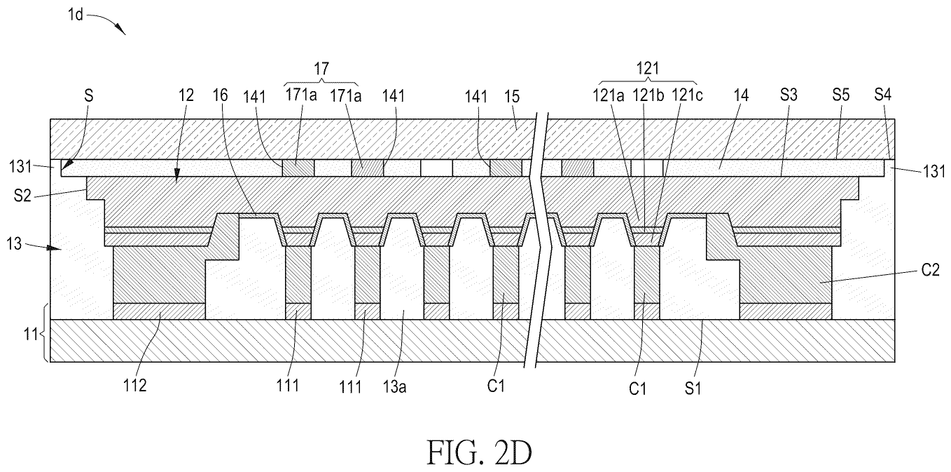

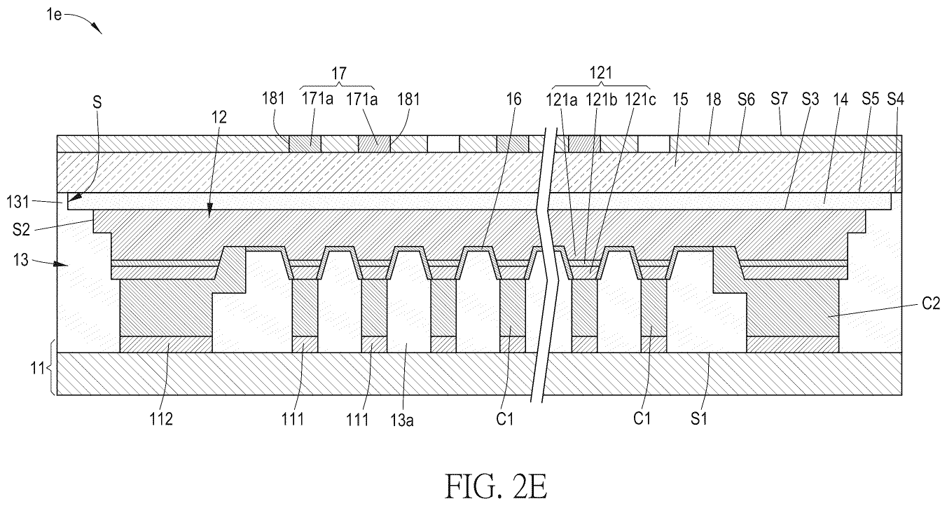

FIGS. 2A to 2E are schematic sectional views of micro LED display devices according to different embodiments of this disclosure.

As shown in FIG. 2A, the component configurations and connections of the micro LED display device 1a of this embodiment are mostly the same as those of the micro LED display device 1 of the previous embodiment. Unlike the previous embodiment, in the micro LED display device 1a of this embodiment, the projection area of the protection layer 15 on the circuit substrate 11 is greater than the projection area of the connection layer 14 on the circuit substrate 11. The support structure 13 protrudes from the surface S3 of the pixel structure layer 12 to form a retaining wall 131, and the retaining wall 131 has a stepped shape. Herein, the retaining wall 131 at least includes a first stage L1 and a second stage L2. The first stage L1 is arranged around the periphery of the connection layer 14, and the second stage L2 is located on the first stage L1 and arranged around the periphery of the protection layer 15. Specifically, the first stage L1 of the stepped retaining wall 131 surrounds the connection layer 14 and connects to the side surface of the connection layer 14, while the second stage L2 surrounds the protection layer 15 and connects to the side surface of the protection layer 15. Furthermore, the thickness of the connection layer 14 is equal to the height of the first stage L1, and the thickness of the protection layer 15 is equal to the height of the second stage L2. In addition, the top surface S6 of the protection layer 15 is leveled with the top surface S4 of the support structure 13. That is, the connection layer 14 and the protection layer 15 are both located in the accommodating space S and embedded in the accommodating space S, and the connection layer 14 and the protection layer 15 are connected to the support structure 13 (the retaining wall 131) closely.

As shown in FIG. 2B, the component configurations and connections of the micro LED display device 1b of this embodiment are mostly the same as those of the micro LED display device 1 of the previous embodiment. Unlike the previous embodiment, in the micro LED display device 1b of this embodiment, the projection area of the protection layer 15 on the circuit substrate 11 is equal to the projection area of the connection layer 14 on the circuit substrate 11. Specifically, in this embodiment, the size of the protection layer 15 is the same as that of the connection layer 14, and the connection layer 14 and the protection layer 15 are both located in the accommodating space S and embedded in the accommodating space S. The connection layer 14 and the protection layer 15 are connected to the retaining wall 131 closely. In addition, the side surface of the protection layer 15 is leveled with the side surface S2 of the connection layer 14.

As shown in FIG. 2C, the component configurations and connections of the micro LED display device 1c of this embodiment are mostly the same as those of the micro LED display device 1 of the previous embodiment. Unlike the previous embodiment, in the micro LED display device 1c of this embodiment, the size of the protection layer 15 is smaller than that of the connection layer 14, so that the projection area of the protection layer 15 on the circuit substrate 11 is less than the projection area of the connection layer 14 on the circuit substrate 11. In addition, a part of the connection layer 14 is located between the protection layer 15 and the pixel structure layer 12, and the other part of the connection layer 14 is located between the side surfaces of the protection layer 15 and the retaining wall 131 of the support structure 13. Accordingly, the protection layer 15 does not directly contact with the retaining wall 131 of the support structure 13, so the connection layer 14 can more closely connect with the retaining wall 131.

As shown in FIG. 2D, the component configurations and connections of the micro LED display device Id of this embodiment are mostly the same as those of the micro LED display device 1 of the previous embodiment. Unlike the previous embodiment, in the micro LED display device 1d of this embodiment, the connection layer 14 is defined with a plurality of separated light conversion regions 141, and each light conversion region 141 corresponds to one of the micro LED units 121. In this embodiment, each light conversion region 141 is overlapped with the corresponding micro LED unit 121 in a direction perpendicular to the top surface S1. In this case, each light conversion region 141 is a through hole formed in the connection layer 14, and the through holes can communicate the top surface S5 of the connection layer 14 with the surface S3 of the pixel structure layer 12. Therefore, the light emitted from the micro LED unit 121 corresponding to the light conversion region 141 can penetrate through the corresponding through hole (the light conversion region 141) and be outputted upward. In other words, the light emitted by the micro LED unit 121 can pass through the through hole.

In addition, the micro LED display device Id of this embodiment may further include a light conversion layer 17, which is disposed in the light conversion regions 141. The light conversion layer 17 is used to convert the wavelength of the light emitted by the corresponding micro LED unit 121. In this embodiment, the light conversion layer 17 includes a plurality of separated light conversion portions 171a and 171b, which are located in the corresponding light conversion regions 141, respectively. Each light conversion portion 171a or 171b corresponds to one of the micro LED units 121. Specifically, in three sub-pixels of one pixel P, the light conversion regions 131 in two sub-pixels are filled with the materials of light conversion portions 171a and 171b for converting the lights into different wavelengths. Herein, the light conversion layer 17 (the light conversion portions 171a and 171b) includes a light conversion material, such as quantum dots, phosphorescent material or fluorescent material. In this embodiment, the light conversion material includes, for example, quantum dots. The quantum dots of different sizes can be excited to produce lights of different colors. For example, the quantum dots of different sizes can be excited by blue light to produce red light and green light. Therefore, in each light conversion region 141 corresponding to the light conversion portion 171a or 171b, the light (e.g. blue light) emitted by the sub-pixel (i.e., the micro LED unit 121) there will be converted by the corresponding light conversion portion (the light conversion portion 171a or 171b) into a preset color (e.g. red or green light). Regarding the third sub-pixel, since the light emitted by this sub-pixel does not need to be converted, the corresponding through hole can be filled or not filled with a light-transmitting gel material.

Moreover, the connection layer 14 of the micro LED display device Id of this embodiment can be a light-absorbing material, such as a black photoresist or a reflective material. For example, the reflective material can be white high-reflection silica gel, which is used to absorb or reflect light so as to prevent light interference between sub-pixels.

In some embodiments, when a thicker light conversion layer 17 (the light conversion portions 171a and 171b) is used for obtaining higher color purity, a thicker connection layer 14 is also required. In some embodiments, in addition to the light conversion portions 171a and 171b, the filter layers (red and green filter materials) can be added to the corresponding light conversion regions 141 so as to improve the color purity of outputted light. In addition, in different embodiments, the micro LED units 121 can also be cooperated with other corresponding light conversion portions (and/or filter portions) to generate lights of other colors (for example but not limited to yellow or white light). It should be understood that, in order to increase the light output efficiency of the micro LED units 121, a reflective layer (not shown) containing a light reflective material may also be disposed at the periphery of the sidewall of each light conversion region 141.

As shown in FIG. 2E, the component configurations and connections of the micro LED display device 1e of this embodiment are mostly the same as those of the micro LED display device 1 of the previous embodiment. Unlike the previous embodiment, the micro LED display device 1e of this embodiment further includes a light processing layer 18, which is arranged on the top surface S6 of the protection layer 15 and is define with a plurality of separated light conversion regions 181. Each light conversion region 181 corresponds to one of the sub-pixels (one micro LED unit 121). The light processing layer 18 can include a light-absorbing material (e.g. black photoresist) for absorbing light or a reflective material (e.g. white high-reflective silicon) for reflecting light. Regarding the other sub-pixel (micro LED unit 121), since the light emitted by this sub-pixel does not need to be converted, the corresponding through hole can be filled or not filled with a light-transmitting gel material.

In addition, the light conversion layer 17 of this embodiment is disposed in the light conversion regions 181 of the light processing layer 18 and is used to convert the wavelength of the light emitted from the corresponding micro LED units 121. Similar to the previous embodiment, the light conversion portions 171a and 171b of the light conversion layer 17 are respectively disposed in the corresponding light conversion regions 181, and one light conversion portion 171a or 171b corresponds to one micro LED unit 121. In addition, it should be understood that a reflective layer containing a light reflective material may also be provided at the periphery of the sidewall of each light conversion region 181 to increase the light output rate.

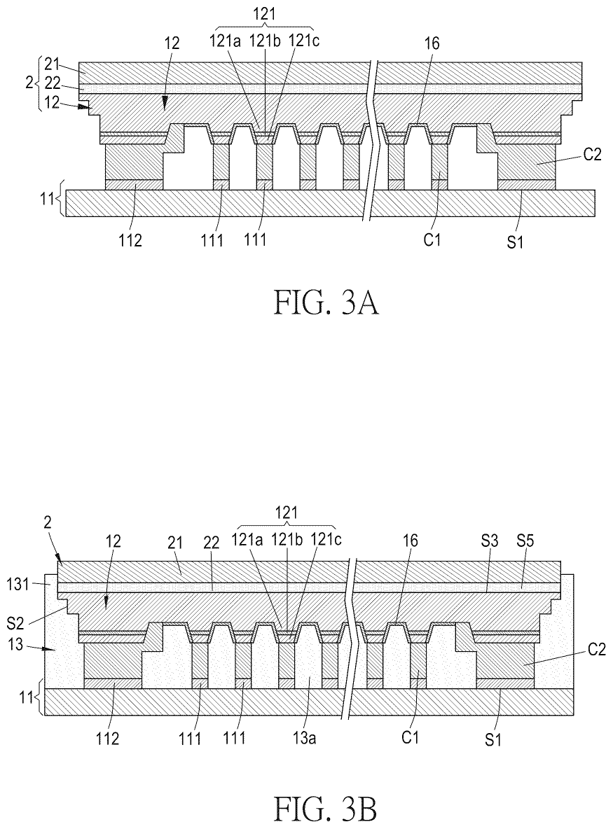

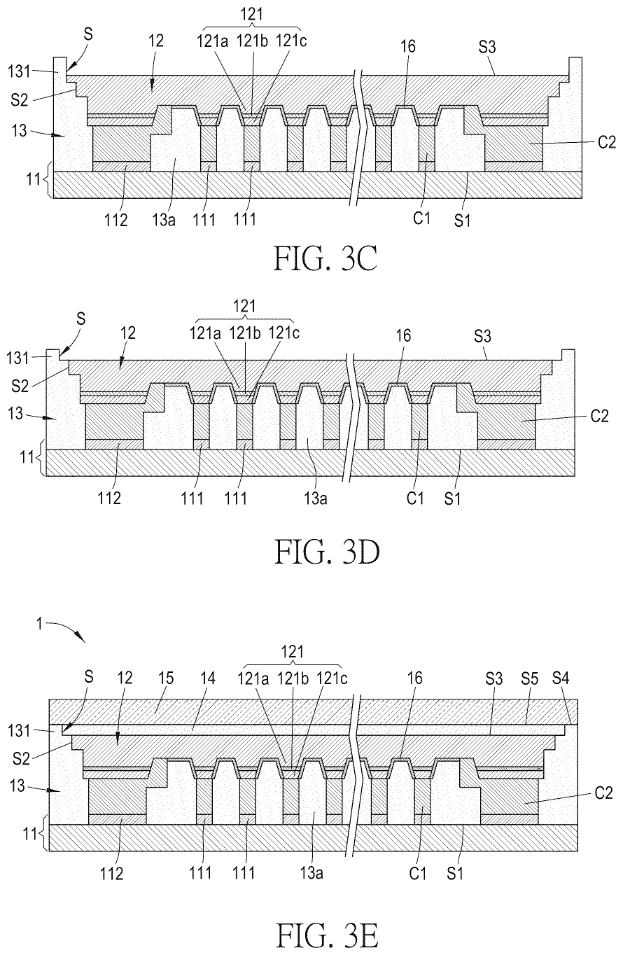

FIGS. 3A to 3E are schematic sectional views showing the manufacturing procedure of a micro LED display device according to an embodiment of this disclosure.

The manufacturing method of the micro LED display device of this embodiment at least includes the following six steps.

As shown in FIG. 3A, the step one is to provide a circuit substrate 11 and a temporary substrate 2, wherein the circuit substrate 11 has a top surface S1, and the temporary substrate 2 includes a carrier plate 21, a bonding layer 22, and a pixel structure layer 12. The pixel structure layer 12 is disposed on the carrier plate 21 via the bonding layer 22, and the pixel structure layer 12 has a plurality of micro LED units 121 disposed separately.

The step two is to aim the micro LED units 121 of the pixel structure layer 12 toward the top surface S1 of the circuit substrate 11 and to electrically connect the micro LED units 121 with the circuit substrate 11. In this embodiment, the temporary substrate 2 is reversed, so the micro LED units 121 face downwardly. Then, the first electrodes 111 of the circuit substrate 11 are electrically connected with the second type semiconductor layer 121c of the corresponding micro LED units via the conductive members C1, respectively. The second electrode 112 of the circuit substrate 11 is used as the common electrode of the pixel structure layer 12, and it is electrically connected with the first semiconductor layer 121a of each micro LED unit 121 via one conductive member C2.

As shown in FIG. 3B, the step three is to form a support structure 13 on the top surface S1 of the circuit substrate 11, to extend the support structure 13 from the top surface S1 to a side surface S2 of the pixel structure layer 12, and to connect the support structure 13 with the pixel structure layer 12, the bonding layer 22, and the carrier plate 21. In this embodiment, the support structure 13 protrudes from the side surface S2 of the pixel structure layer 12, and connects the side surface S2 of the pixel structure layer 12 and the side surfaces of the bonding layer 22 and the carrier plate 21. Moreover, this step three of forming the support structure 13 on the top surface S1 of the circuit substrate 11 is further to fill the material of the support structure 13 between the pixel structure layer 12 and the circuit substrate 11 so as to form the filling layer 13a. Specifically, the support structure 13 can be formed by the same process and using the same material to surround the periphery of the pixel structure layer 12 and contact the side surface S2 of the pixel structure layer 12, the bonding layer 22 and the side surface of the carrier plate 21. In addition, the material of the support structure 13 can be further filled between the pixel structure layer 12 and the top surface S1 of the circuit substrate 11 to form the filling layer 13a (at the same time or at different times), so that the support structure 13 and the filling layer 13a are integrally formed as one piece. This configuration can increase the production yield and product reliability. Of course, in different embodiments, the support structure 13 and the filling layer 13a may be independent components, and the materials thereof may be the same or different. This disclosure is not limited thereto.

As shown in FIG. 3C, the step four is to remove the carrier plate 21 and the bonding layer 22 to expose the surface S3 of the pixel structure layer 12. In this case, the support structure 13 protrudes from the surface S3 of the pixel structure layer 12 away from the circuit substrate 11, and the support structure 13 and the surface S3 of the pixel structure layer 12 form an accommodating space S. Since the filling layer 13a is disposed between the pixel structure layer 12 and the circuit substrate 11, the bonding strength between the pixel structure layer 12 and the circuit substrate 11 can be improved, and the pixel structure layer 12 and the circuit substrate 11 will not be separated when the carrier plate 21 is removed.

Afterwards, the step five is to form a connection layer 14 in the accommodating space S. To be noted, before the step five, as shown in FIG. 3D, a thinning process can be performed in advance to reduce the thickness of the pixel structure layer 12, and at the same time, trim the height of the retaining wall 131 of the support structure 13 protruding from the surface S2 of the pixel structure layer 12, thereby defining the shape and thickness of the connection layer 14 filling in the accommodating space S by the retaining wall 131. In some embodiments, the thickness of the first type semiconductor layer 121a of the pixel structure layer 12 can be reduced by using a dry etching process, thereby reducing the thickness of the pixel structure layer 12. In this dry etching process, the height of the retaining wall 131 is also trimmed so as to meet the requirement. To be noted, in this embodiment, the etching rate of the support structure 13 is different from that of the pixel structure layer 12. In some embodiments, the etching rate of the support structure 13 is greater than the etching rate of the pixel structure layer 12, so that the height of the retaining wall 131 can be controlled while the pixel structure layer 12 is thinned, thereby obtaining a suitable accommodating space for completely attaching the protection layer 15. Afterwards, as shown in FIG. 3E, the step five is performed to form the connection layer 14 in the accommodating space S. In this embodiment, the height of the retaining wall 131 is equal to the thickness of the connection layer 14.

Finally, as shown in FIG. 3E, the step six is performed to dispose a protection layer 15 on the connection layer 14, so that the protection layer 15 is connected with the pixel structure layer 12 via the connection layer 14, thereby finishing the manufacturing process of the micro LED display device 1. In this embodiment, the Young's modulus of the protection layer 15 is greater than that of the support structure 13, and the Young's modulus of the protection layer 15 is also greater than that of the connection layer 14. Moreover, in this embodiment, the top surface S5 of the connection layer 14 is leveled with the top surface S4 of the support structure 13. In addition, in this embodiment, the size of the protection layer 15 is larger than that of the connection layer 14, and the projection of the protection layer 15 on the circuit substrate 11 is completely overlapped with the projections of the connection layer 14 and the support structure 13 on the circuit substrate 11.

The other technical features of the manufacturing method of the micro LED display device of this embodiment can refer to those of the previous embodiments, so the detailed descriptions thereof will be omitted.

To sum up, in the micro LED display device and the manufacturing method of the same of this disclosure, the pixel structure layer is disposed on the top surface of the circuit substrate and includes a plurality of micro LED units arranged separately, and the micro LED units face the top surface and are electrically connected with the circuit substrate. The support structure is disposed on the top surface of the circuit substrate, extending from the top surface of the circuit substrate to the pixel structure layer, and connected with the side surface of the pixel structure layer. The support structure protrudes from a surface of the pixel structure layer away from the circuit substrate, and the support structure and the surface of the pixel structure layer form an accommodating space. The connection layer is disposed in the accommodating space, and the protection layer is disposed on the connection layer. Based on the structural design of this disclosure, the micro LED display device can prevent the intrusion of moisture and dusts, thereby remaining the properties of the micro LED display device and improving the lifetime thereof.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A micro light-emitting diode display device, comprising:
a circuit substrate having a top surface;
a pixel structure layer disposed on the top surface of the circuit substrate, wherein the pixel structure layer has a plurality of micro light-emitting diode units disposed separately, the micro light-emitting diode units face the top surface of the circuit substrate and are electrically connected with the circuit substrate, and the pixel structure layer further includes a side surface;
a support structure disposed on the top surface of the circuit substrate, extending from the top surface of the circuit substrate to the pixel structure layer and connected with the side surface of the pixel structure layer, wherein the support structure protrudes from a surface of the pixel structure layer away from the circuit substrate, and the support structure and the surface of the pixel structure layer form an accommodating space;
a connection layer disposed in the accommodating space; and
a protection layer disposed on the connection layer.

2. The micro light-emitting diode display device of claim 1, wherein the circuit substrate further includes a display area and a non-display area, the non-display area is arranged around a periphery of the display area, and the support structure is configured in the non-display area.

3. The micro light-emitting diode display device of claim 1, further comprising:
a filling layer disposed between the pixel structure layer and the top surface of the circuit substrate.

4. The micro light-emitting diode display device of claim 3, wherein the support structure and the filling layer are integrally formed as one piece.

5. The micro light-emitting diode display device of claim 3, wherein the filling layer contains at least an air bubble.

6. The micro light-emitting diode display device of claim 1, wherein the protection layer is arranged on the support structure and the connection layer, and a projection of the protection layer on the circuit substrate is within a projection of the support structure on the circuit substrate.

7. The micro light-emitting diode display device of claim 1, wherein the support structure protrudes from the surface of the pixel structure layer to form a retaining wall, the retaining wall has a stepped shape and at least comprises a first stage and a second stage, the first stage is arranged around a periphery of the connection layer, and the second stage is located on the first stage and arranged around a periphery of the protection layer.

8. The micro light-emitting diode display device of claim 1, wherein the protection layer and the connection layer are located in the accommodating space.

9. The micro light-emitting diode display device of claim 1, wherein a projection of the protection layer on the circuit substrate is less than or equal to a projection of the connection layer on the circuit substrate.

10. The micro light-emitting diode display device of claim 9, wherein a part of the connection layer is located between the support structure and a side surface of the protection layer.

11. The micro light-emitting diode display device of claim 1, wherein Young's modulus of the protection layer is greater than that of the support structure, and the Young's modulus of the protection layer is greater than that of connection layer.

12. A manufacturing method of a micro light-emitting diode display device, comprising:
providing a circuit substrate and a temporary substrate, wherein the circuit substrate has a top surface, the temporary substrate comprises a carrier plate, a bonding layer and a pixel structure layer, the pixel structure layer is disposed on the carrier plate via the bonding layer, and the pixel structure layer has a plurality of micro light-emitting diode units disposed separately;
aiming the micro light-emitting diode units of the pixel structure layer toward the top surface and electrically connecting the micro light-emitting diode units with the circuit substrate;
forming a support structure on the top surface of the circuit substrate, extending the support structure from the top surface to a side surface of the pixel structure layer, and connecting the support structure with the pixel structure layer, the bonding layer and the carrier plate;
removing the carrier plate and the bonding layer to expose a surface of the pixel structure layer, wherein the support structure protrudes from the surface of the pixel structure layer away from the circuit substrate, and the support structure and the surface of the pixel structure layer form an accommodating space;
forming a connection layer in the accommodating space; and
disposing a protection layer on the connection layer, so that the protection layer is connected with the pixel structure layer via the connection layer.

13. The manufacturing method of claim 12, in the step of forming the support structure on the surface of the circuit substrate, further comprising:
further filling material of the support structure between the pixel structure layer and the circuit substrate.

14. The manufacturing method of claim 12, before the step of forming the connection layer in the accommodating space, further comprising:
performing an etching process to reduce a thickness of the pixel structure layer and to decrease a height of a retaining wall of the support structure, which protrudes from the surface of the pixel structure layer.

15. The manufacturing method of claim 14, wherein an etching rate of the support structure is different from that of the pixel structure layer.
